(19) United States
(12) Patent Application Publication
(10) Pub. No.: US 2014/0137932 A1
(43) Pub. Date: May 22, 2014

(54) SOLAR CELL AND METHOD OF FABRICATING THE SAME

(71) Applicant: Electronics and Telecommunications Research Institute, Daejeon (KR)

(72) Inventors: Daehyung CHO, Seoul (KR); Yong-Duck Chung, Daejeon (KR)

(21) Appl. No.: 13/908,100

(22) Filed: Jun. 3, 2013

(30) Foreign Application Priority Data
Nov. 19, 2012 (KR) 10-2012-0130991

(51) Int. Cl. H01L 31/0216; H01L 31/18

(52) U.S. Cl. CPC H01L 31/02168; H01L 31/18
USPC 136/256; 438/69

(57) ABSTRACT

Provided are a solar cell and a method of fabricating the same. The method may include forming a light absorbing layer on a substrate, forming a window electrode on the light absorbing layer, and attaching a light scattering sheet with a concavo-convex structure to the window electrode. The light scattering sheet may be a single layer made of adhesive material.

### CROSS-REFERENCE TO RELATED APPLICATIONS

This U.S. non-provisional patent application claims priority under 35 U.S.C. §119 to Korean Patent Application No. 10-2012-0130991, filed on Nov. 19, 2012, in the Korean Intellectual Property Office, the entire contents of which are hereby incorporated by reference.

### BACKGROUND OF THE INVENTION

Example embodiments of the inventive concept relate to a solar cell and a method of fabricating the same, and in particular, to a solar cell with a light scattering sheet and a method of fabricating the same.

A solar cell is a semiconductor device that converts sunlight into electricity. There have been suggested several technologies to realize a large area, low cost, and highly efficient solar cell.

A thin-film solar cell is superior to a silicon solar cell, in terms of a short energy payback time, a thin thickness, and a large area. As the result of innovations in fabrication technology, it is expected to be able to reduce greatly a fabrication cost of the thin film solar cell. In addition, to improve photoelectric conversion efficiency of the thin-film solar cell, there have been many researches to develop a CIS thin-film solar cell having a CIS thin film (e.g., of copper-indium-gallium-selenium (Cu—In—Ga—Se) or copper-zinc-tin-selenium (Cu—Zn—Sn—Se)).

A light absorbing layer of the thin-film solar cell may be configured to absorb sunlight that may be used to generate electron-hole pairs. The more sunlight the light absorbing layer absorbs, the more an electric energy is generated. Accordingly, it is possible to improve photoelectric conversion efficiency of the thin-film solar cell.

### SUMMARY

Example embodiments of the inventive concept provide a solar cell with improved photoelectric conversion efficiency and a method of fabricating the same.

According to example embodiments of the inventive concepts, a method of fabricating a solar cell may include forming a light absorbing layer on a substrate, forming a window electrode on the light absorbing layer, and attaching a light scattering sheet with a concavo-convex structure to the window electrode. The light scattering sheet may be a single layer made of adhesive material.

In example embodiments, the light scattering sheet may be formed by: providing a roll with a concavo-convex structure on a plane sheet including the adhesive material, and rolling the roll to transfer the concavo-convex structure onto the plane sheet.

In example embodiments, the adhesive material may include at least one of ethylene vinyl acetate (EVA) and poly vinyl butyral (PVB).

In example embodiments, the concavo-convex structure may include a plurality of patterns, each of which may be shaped like pyramid, inverted pyramid, cone, cylinder, or square pillar.

According to example embodiments of the inventive concepts, a solar cell may include a light absorbing layer on a substrate, and a light scattering sheet on the light absorbing layer to have a concavo-convex portion. The light scattering sheet may be a single layer made of adhesive material.

In example embodiments, the adhesive material may include at least one of ethylene vinyl acetate (EVA) and poly vinyl butyral (PVB).

In example embodiments, the light scattering sheet has a thickness of 0.01 mm to 10 cm.

In example embodiments, the solar cell may further include a back-side electrode between the substrate and the light absorbing layer, a buffer layer between the light absorbing layer and the light scattering sheet, and a window electrode between the buffer layer and the light scattering sheet.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic diagram that is provided to describe a solar cell according to example embodiments of the inventive concept.

FIG. 2 is a sectional view of a CIGS solar cell according to example embodiments of the inventive concept.

FIG. 3 is a sectional view of a CIGS solar cell according to other example embodiments of the inventive concept.

FIG. 4 is a flow chart illustrating a method of fabricating a CIGS solar cell, according to example embodiments of the inventive concept.

FIGS. 5 through 8 are sectional views illustrating a method of fabricating a CIGS solar cell, according to example embodiments of the inventive concept.

FIG. 9 is a schematic diagram illustrating a method of fabricating a light scattering sheet, according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

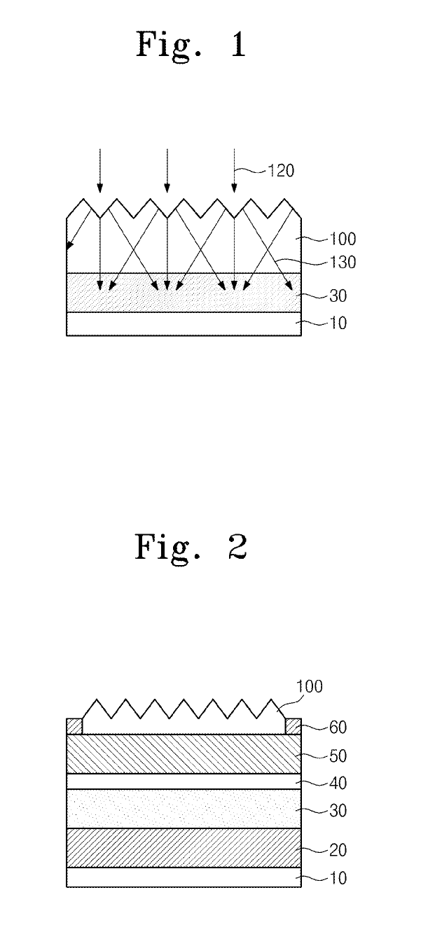

FIG. 1 is a schematic diagram that is provided to describe a solar cell according to example embodiments of the inventive concept.

Referring to FIG. 1, a solar cell may include a substrate 10, a light scattering sheet 100 on the substrate 10, and a light absorbing layer 30 between the substrate 10 and the light scattering sheet 100. The substrate 10 may include at least one of ceramics (e.g., soda-lime glass, alumina, and quartz), semiconductor materials (e.g., silicon), metallic materials (e.g., stainless steel, copper, chromium, molybdenum), or polymeric materials. In other example embodiments, as shown in FIG. 1, the substrate 10 may be provided between the light scattering sheet 100 and the light absorbing layer 30. Here, the substrate 10 may be transparent. The light absorbing layer 30 may include chalcopyrite compound semiconductor (e.g., crystalloid silicon, poly silicon, amorphous silicon, CuInSe, CuInSe₂, CuInGaSe, CuInGaSe₂), II-VI compound semiconductor (e.g., CdTe), or III-V compound semiconductor (e.g., GaAs and InP).

The light scattering sheet 100 may include an adhesive material. In example embodiments, the light scattering sheet 100 may be a single layer made of the adhesive material. For example, the light scattering sheet 100 may include at least one of ethylene vinyl acetate (EVA) and poly vinyl butyral (PVB). The light scattering sheet 100 may include an upper portion of concavo-convex structure. For example, the concavo-convex upper portion may include a plurality of patterns, each of which is shaped like pyramid, inverted pyramid, cone, cylinder, or square pillar. A light 120 incident from the outside may be scattered by the concavo-convex upper portion of the light scattering sheet 100 to form a scattered light 130. The scattered light 130 may be incident into the light absorbing layer 30 with various angles and be transmitted in the light absorbing layer 30 with an increased optical propagation distance. This makes it possible to improve light absorptivity in the light absorbing layer 30 and thereby photoelectric conversion efficiency of the solar cell. The light scattering sheet 100 may be configured to have light transmittance of about 50% to about 100% and a haze ratio of about 1% to about 100%. In addition, the light scattering sheet 100 may have a thickness of about 0.01 mm to about 10 cm.

FIG. 2 is a sectional view of a CIGS solar cell according to example embodiments of the inventive concept.

Referring to FIG. 2, a solar cell according to example embodiments of the inventive concept may include a substrate 10, a back-side electrode 20 on the substrate 10, a light absorbing layer 30 on the back-side electrode 20, a buffer layer 40 on the light absorbing layer 30, a window electrode 50 on the buffer layer 40, and a grid 60 and a light scattering sheet 100 on the window electrode 50.

The substrate 10 may include or be a soda-lime glass substrate, a ceramic substrate, a semiconductor substrate (e.g., of silicon), a metal substrate, or a polymer substrate. The back-side electrode 20 may include an opaque metal layer (e.g., of molybdenum). The light absorbing layer 30 may include a chalcopyrite compound semiconductor (e.g., CuInSe, CuInSe₂, CuInGaSe, or CuInGaSe₂). The buffer layer 40 may be configured to reduce an energy band gap between the window electrode 50 and the light absorbing layer 30. For example, the buffer layer 40 may have an energy band gap that is greater than that of the light absorbing layer 30 and is smaller than that of the window electrode 50. In example embodiments, the buffer layer 40 may be formed of a CdS layer.

The window electrode 50 may include indium tin oxide or zinc oxide. In example embodiments, the window electrode 50 may include a metal oxide layer and a metal layer. The grid 60 may be electrically connected to the window electrode 50. The grid 60 may include at least one metal layer (e.g., of gold, silver, aluminum, or indium).

The light scattering sheet 100 may be provided on the window electrode 50. The light scattering sheet 100 may include an adhesive material, for example, at least one of ethylene vinyl acetate (EVA) and poly vinyl butyral (PVB). The light scattering sheet 100 may be a single layer made of the adhesive material. The light scattering sheet 100 may include an upper portion of concavo-convex structure. In example embodiments, the concavo-convex upper portion may include a plurality of patterns, each of which is shaped like pyramid. The light scattering sheet 100 may be attached to the window electrode 50 by the adhesive material. The light scattering sheet 100 may change an incident light to a scattered light using the concavo-convex structure therein. The scattered light may be incident into the light absorbing layer 30 with various angles and be transmitted in the light absorbing layer 30 with an increased optical propagation distance. This makes it possible to improve light absorptivity in the light absorbing layer 30 and thereby photoelectric conversion efficiency of the solar cell. The light scattering sheet 100 may be configured to have light transmittance of about 90% and a haze ratio of about 30%. In addition, the light scattering sheet 100 may have a thickness of about 0.1 mm.

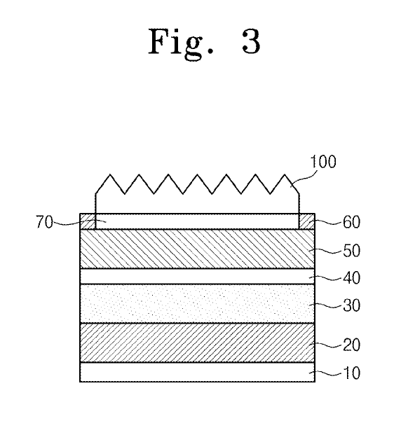

FIG. 3 is a sectional view of a CIGS solar cell according to other example embodiments of the inventive concept. For concise description, an element previously described with reference to FIG. 2 may be identified by a similar or identical reference number without repeating an overlapping description thereof.

Referring to FIG. 3, a solar cell according to other example embodiments of the inventive concept may include a substrate 10, a back-side electrode 20 on the substrate 10, a light absorbing layer 30 on the back-side electrode 20, a buffer layer 40 on the light absorbing layer 30, a window electrode 50 on the buffer layer 40, a grid 60 and a light scattering sheet 100 on the window electrode 50, and an anti-reflecting layer 70 between the window electrode 50 and the light scattering sheet 100.

The anti-reflecting layer 70 may be configured to prevent sunlight to be incident to the light absorbing layer 30 from being reflected. In example embodiments, the anti-reflecting layer 70 may have a refractive index between those of the light scattering sheet 100 and the window electrode 50. The anti-reflecting layer 70 may include or be formed of, for example, magnesium fluoride (MgF₂). The light scattering sheet 100 may be provided on the anti-reflecting layer 70. The light scattering sheet 100 may include an adhesive material, for example, at least one of ethylene vinyl acetate (EVA) and poly vinyl butyral (PVB). The light scattering sheet 100 may be a single layer made of the adhesive material.

The light scattering sheet 100 may include an upper portion of concavo-convex structure. The light scattering sheet 100 may be attached to the anti-reflecting layer 70 by the adhesive material.

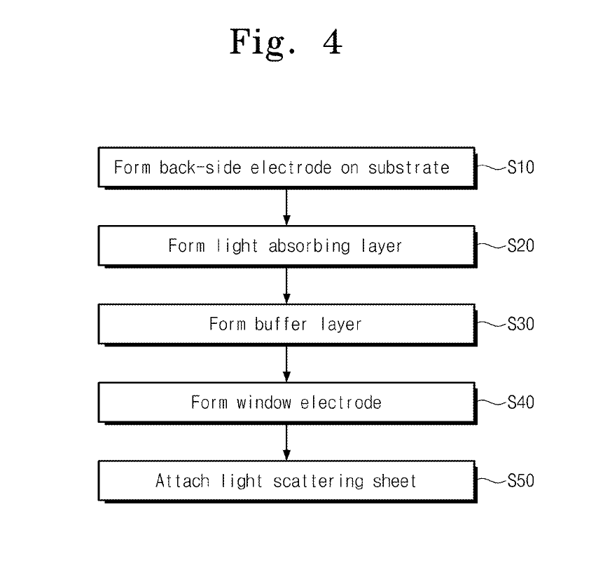

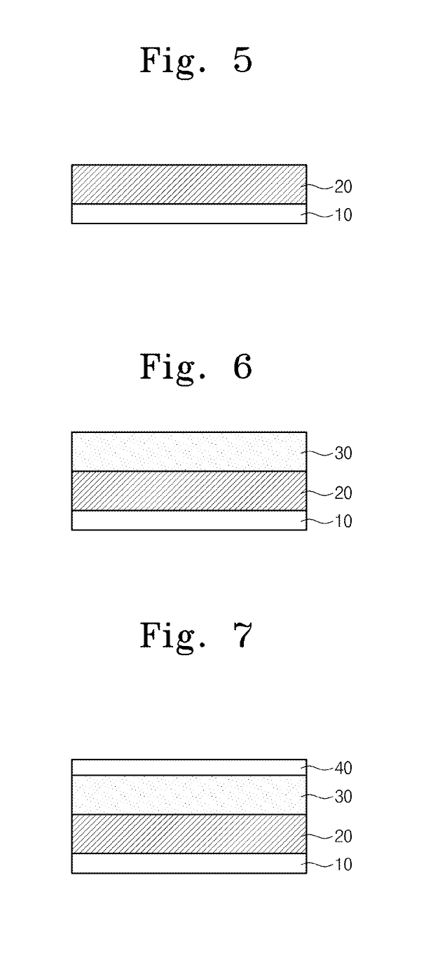

FIG. 4 is a flow chart illustrating a method of fabricating a CIGS solar cell, according to example embodiments of the inventive concept, and FIGS. 5 through 8 are sectional views illustrating a method of fabricating a CIGS solar cell, according to example embodiments of the inventive concept.

Referring to FIGS. 4 and 5, a back-side electrode 20 may be formed on a substrate 10 (in S10). The substrate 10 may include or be a soda-lime glass substrate, a ceramic substrate, a semiconductor substrate (e.g., of silicon), a metal substrate, or a polymer substrate. The back-side electrode 20 may include an opaque metal layer (e.g., of molybdenum). The back-side electrode 20 may be formed using a vacuum deposition process, e.g., sputtering or evaporation.

Referring to FIGS. 4 and 6, a light absorbing layer 30 may be formed on the back-side electrode 20 (in S20). The light absorbing layer 30 may include a chalcopyrite compound semiconductor (e.g., CuInSe, CuInSe₂, CuInGaSe, or CuInGaSe₂). The light absorbing layer 80 may be formed using a vacuum deposition process, e.g., sputtering or co-evaporation.

Referring to FIGS. 4 and 7, a buffer layer 40 may be formed on the light absorbing layer 30 (in S30). The buffer layer 40 may be a CdS layer. The buffer layer 4 may be formed using, for example, a chemical bath deposition process.

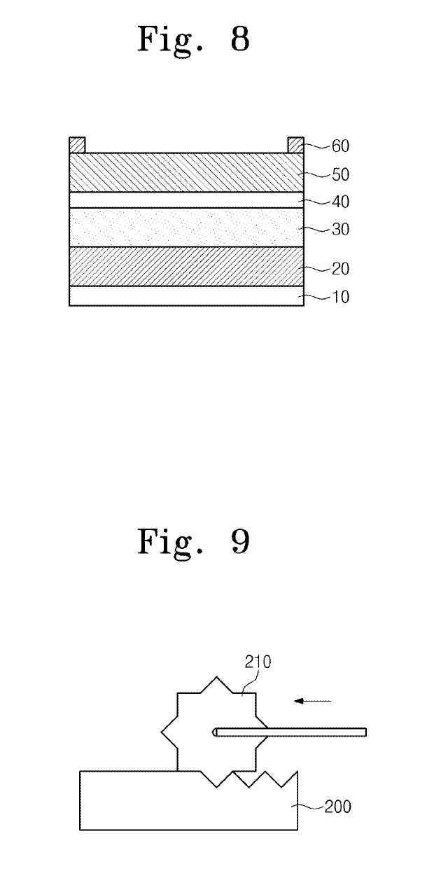

Referring to FIGS. 4 and 8, a window electrode 50 may be formed on the buffer layer 40 (in S40). The window electrode 50 may include indium tin oxide or zinc oxide. In example embodiments, the window electrode 50 may include a metal oxide layer and/or a metal layer. The window electrode 50 may be formed using a vacuum deposition process (e.g., physical vapor deposition). In example embodiments, a grid 60 may be further formed on the window electrode 50. In other example embodiments, as described with reference to FIG. 3, the grid 60 and an anti-reflecting layer 70 may be further formed on the window electrode 50. The grid 60 may be configured to exhaust electrons to be generated in the light absorbing layer 30. The grid 60 may be electrically connected to the window electrode 50. The grid 60 may include at least one metal layer (e.g., of gold, silver, aluminum, or indium). The grid 60 may be formed using a vacuum deposition process, e.g., sputtering or evaporation. The anti-reflecting layer 70 may be formed to prevent sunlight to be incident into the light absorbing layer 30 from being reflected. For example, the anti-reflection layer 70 may include magnesium fluoride (MgF₂). The anti-reflection layer 70 may be formed using a vacuum deposition process, e.g., sputtering or evaporation.

Referring back to FIGS. 2 and 4, a light scattering sheet 100 may be attached to the window electrode 50 (in S50). FIG. 9 is a schematic diagram illustrating a method of fabricating a light scattering sheet, according to example embodiments of the inventive concept. Referring to FIG. 9, a plane sheet 200 may be provided to include an adhesive material. The plane sheet 200 may be a single layer made of the adhesive material. The plane sheet 200 may include at least one of ethylene vinyl acetate (EVA) and poly vinyl butyral (PVB). A roll 210 with a concavo-convex surface structure may be provided on the plane sheet 200. The concavo-convex surface structure may include a plurality of patterns, each of which is shaped like pyramid, inverted pyramid, cone, cylinder, or square pillar. Thereafter, the roll 210 may be rolled to transfer the concavo-convex surface structure onto the plane sheet 200 and form the light scattering sheet 100. Next, the light scattering sheet 100 may be attached to the window electrode 60 by the adhesive material. However, according to other embodiments, the anti-reflecting layer 70 may be formed on the window electrode 50 as described with reference to FIG. 3, and in this case, the light scattering sheet 100 may be attached to the anti-reflecting layer 70 by the adhesive material.

If the concavo-convex structure is formed by depositing a thin film and etching the thin film in dry or wet etching manner, a structure of the thin film may be changed during or after the etching process, and thus, the solar cell may have deteriorated electric characteristics. In addition, the use of the deposition and etching processes may complicate the process of fabricating the solar cell. By contrast, according to example embodiments of the inventive concept, the light scattering sheet may include the adhesive material and the concavo-convex structure of the light scattering sheet may be formed by a roll with a concavo-convex surface. The light scattering sheet may be easily attached to the window electrode or the anti-reflecting layer of the solar cell using the adhesive material. Further, due to the presence of the concavo-convex structure, the light scattering sheet may change a light incident from the outside to a scattered light, which may be incident into the light absorbing layer, and thus, light absorptivity of the light absorbing layer may be improved. In other words, according to example embodiments of the inventive concept, the solar cell may include the light scattering sheet with the concavo-convex structure, which may be provided on the window electrode or the anti-reflecting layer using a simple attaching method. For all that, light absorptivity of the solar cell can be increased, and photoelectric conversion efficiency of the solar cell can be improved.

According to example embodiments of the inventive concept, a light scattering sheet with a concavo-convex shape may be used to realize a solar cell with improved photoelectric conversion efficiency.

In addition, by using a light scattering sheet with an adhesive material, it is possible to fabricate a solar cell with improved photoelectric conversion efficiency with ease.

While example embodiments of the inventive concepts have been particularly shown and described, it will be understood by one of ordinary skill in the art that variations in form and detail may be made therein without departing from the spirit and scope of the attached claims.

What is claimed is:

1. A method of fabricating a solar cell, comprising:
forming a light absorbing layer on a substrate;
forming a window electrode on the light absorbing layer; and
attaching a light scattering sheet with a concavo-convex structure to the window electrode,
wherein the light scattering sheet is a single layer made of adhesive material.

2. The method of claim 1, wherein the light scattering sheet is formed by:
providing a roll with a concavo-convex structure on a plane sheet including the adhesive material; and
rolling the roll to transfer the concavo-convex structure onto the plane sheet.

3. The method of claim 1, wherein the adhesive material comprises at least one of ethylene vinyl acetate (EVA) and poly vinyl butyral (PVB).

4. The method of claim 1, wherein the concavo-convex structure comprises a plurality of patterns, each of which is shaped like pyramid, inverted pyramid, cone, cylinder, or square pillar,

5. A solar cell, comprising:
a light absorbing layer on a substrate; and
a light scattering sheet on the light absorbing layer to have a concavo-convex portion,
wherein the light scattering sheet is a single layer made of adhesive material.

6. The solar cell of claim 5, wherein the adhesive material comprises at least one of ethylene vinyl acetate (EVA) and poly vinyl butyral (PVB).

7. The solar cell of claim 5, wherein the light scattering sheet has a thickness of 0.01 mm to 10 cm.

8. The solar cell of claim 5, further comprising:
a back-side electrode between the substrate and the light absorbing layer;
a buffer layer between the light absorbing layer and the light scattering sheet; and
a window electrode between the buffer layer and the light scattering sheet.
